(19) United States
(12) Patent Application Publication
(10) Pub. No.: US 2018/0232746 A1
(43) Pub. Date: Aug. 16, 2018

(54) STATIC ELECTRICITY SENSING APPLICATIONS IN RETAIL ENVIRONMENT

(71) Applicant: Wal-Mart Stores, Inc., Bentonville, AR (US)

(72) Inventors: Nicholaus Adam Jones, Fayetteville, AR (US); Matthew Dwain Biermann, Fayetteville, AR (US); Steven Lewis, Bentonville, AR (US)

(21) Appl. No.: 15/879,856

(22) Filed: Jan. 25, 2018

Related U.S. Application Data
(60) Provisional application No. 62/457,519, filed on Feb. 10, 2017.

(51) Int. Cl. G06Q 30/02; G01R 19/00; H04W 4/35; H04W 4/33; H04W 4/38

(52) U.S. Cl. CPC G06Q 30/0201; G01R 19/0046; H04W 4/38; H04W 4/33; H04W 4/35

(57) ABSTRACT

A system for determining a shopping metric from static electricity comprises a plurality of static electricity sensors; a monitoring server that processes signals generated by the static electricity sensors and determines from the processed signals a store metric; and a static electricity measurement database that stores the store metric for subsequent retrieval for analysis.

### RELATED APPLICATIONS

This application claims the benefit of U.S. Provisional Patent Application No. 62/457,519 filed Feb. 10, 2017 and entitled “Static Electricity Sensing Applications in Retail Environment”, the contents of which are incorporated herein in their entirety.

### TECHNICAL FIELD

The present inventive concepts relate generally to static electricity sensors, and more specifically, to systems and methods that include static electricity sensors used in a retail shopping environment.

### BACKGROUND

Electricity is a well-known type of energy used to power modern homes, commercial buildings, transportation vehicles, and electronic devices, commonly known as “current electricity.” Static electricity is another type of electricity, but unlike current electricity, static electricity is prevalent at one location, and results from the imbalance between negative and positive charges in an object, which can build up on the surface of the objects, and be discharged, for example by rubbing an object such as a balloon against another object such as a person's hair.

In retail environments, static electricity is prevalent due to foot traffic from customers, electrical charges that build up on a shopping cart due to the interaction between the cart wheels and the ground surface, and so on. It is desirable to detect and process static electricity for use in store-related operations.

### SUMMARY

In one aspect, a system for determining a store metric from static electricity, comprises a plurality of static electricity sensors arranged in a retail environment that detect an electrostatic field produced by a static electric charge, the electrostatic field generated by a repeatable action; a monitoring server that receives and processes signals generated by the static electricity sensors in response to the detected electrostatic field and generates an electronic record for each action of the repeatable action, the electronic record including contextual data regarding the action, the contextual data in the electronic record including at least one of a time, a location, and an amount of the generated electrostatic field; a metric processing device that generates a store metric regarding the repeatable action from the electronic records; and a static electricity measurement database that electronically stores the store metric for subsequent retrieval for analysis.

In some embodiments, the metric includes at least one of number of shoppers, shopping carts, shopping bags, or a placement of a box on a pallet.

In some embodiments, the static electricity sensors are positioned at a store checkout area or a warehouse having pallets.

In some embodiments, the static electricity sensors detect static electricity at wheels of the shopping carts.

In some embodiments, the static electricity sensors detect static electricity from the opening and closing of the shopping bags.

In some embodiments, each time a shopping bag is opened or closed, the system determines where the static is originated according to intensity and arrival times.

In some embodiments, various store metrics are monitored by counting a number of shopping bags opened during a predetermined period of time.

In some embodiments, the system monitors static electricity in an area, and determines where static electricity sources originate from based upon intensity and arrival times from the sensors.

In some embodiments, the static electricity sensors sense other shopping events such as counting money, detecting a location of a shopping cart, detecting acquisition of store items, and detecting shopper actions.

In some embodiments, the sensor includes an electroscope performing coulomb electronic force detection.

In some embodiments, the sensors are positioned on the pallets.

In some embodiments, a system further comprises a product movement work order database.

In some embodiments, the action includes at least one of human foot traffic and a shopping cart wheel motion and the sensor signals include data that distinguishes the human foot traffic from the shopping cart wheel motion by the amount of the generated electrostatic field.

In another aspect, a system for determining a shopping metric from static electricity, comprises a plurality of static electricity sensors that determine a status of a box on a pallet in response to detected static electricity, and convert the static electricity into output signals; and a monitoring server that processes the converted output signals to establish an origination source of the static electricity, and determines from the processed signals a store metric.

In some embodiments, the system further comprises a static electricity measurement database that stores the store metric for subsequent retrieval for analysis.

In some embodiments, the static electricity sensors determine the origination source by performing a triangulation technique.

In some embodiments, the static electricity sensors determine the origination source based upon intensity and arrival times from the sensors.

In some embodiments, the sensors determine if there are static electrical charges on the surface of the pallet.

In another aspect, a method of use of static electricity for determining a store metric, comprises receiving by a plurality of static electricity sensors a source of static electricity; converting the source of static electricity into digital data; storing the digital data for subsequent retrieval for analysis; and analyzing the digital data to determine the store metric.

### BRIEF DESCRIPTION OF THE DRAWINGS

FIG. 1 is a schematic diagram of an environment in which applications of a static electricity sensing system may be practiced.

FIG. 2 is a flow diagram of a method for determining a status of boxes loaded on a pallet and removed from the pallet, in accordance with some embodiments.

FIG. 3 is a plan view of a store at which the method of FIG. 2 may be implemented, in accordance with some embodiments.

FIG. 4 is a flow diagram of a method for counting money at a point of sale location, in accordance with some embodiments.

FIG. 5 is a plan view of a store at which the method of FIG. 4 may be implemented, in accordance with some embodiments.

FIG. 6 is a flow diagram of a method for counting shopping carts at a point of sale location, in accordance with some embodiments.

FIG. 7 is a plan view of a store at which the method of FIG. 6 may be implemented, in accordance with some embodiments.

FIG. 8 is a flow diagram of a method for counting shopping bags at a point of sale location, in accordance with some embodiments.

FIG. 9 is a plan view of a store at which the method of FIG. 6 may be implemented, in accordance with some embodiments.

### DETAILED DESCRIPTION OF EMBODIMENTS

In brief overview, systems and methods are provided that sense the presence of static electricity for use in collecting data used for processing in a shopping environment. The detection and measurement of electrostatic fields or electrical charges around store-related objects permits the determined amount to be stored for future retrieval and processing.

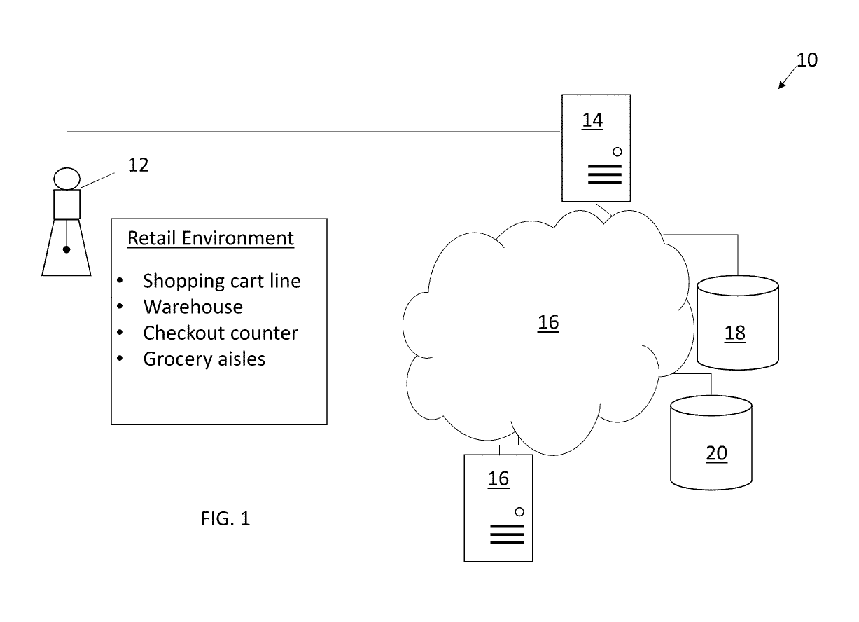

FIG. 1 is a schematic diagram of an environment in which applications of a static electricity sensing system may be practiced.

In some embodiments, a static electricity sensing system 10 includes at least one static electricity sensor 12, a monitoring server 14, a metric processing device 16, a static electricity measurement database 18, and a product movement work order database 20.

In some embodiments, the static electricity sensor 12 may detect electrostatic fields or electrical charges generated between store-related objects, for example, between a shopping cart wheel and the floor surface or between a warehouse pallet and a stocked box on the pallet, by including electroscope features that perform coulomb electronic force detection or the like or any other device that can detect electrostatic fields. In some embodiments, a sensor 12 includes an electroscope or related device that senses and processes a detected amplification of such charges.

In some embodiments, the sensors 12 are positioned at locations in a retail environment where static electricity may be generated, and detected for analysis. In one example, the sensors 12 may be positioned on the pallet where detection is desired for determining whether boxes are being loaded onto the pallet or unloaded from the pallet. In another example, the sensors 12 are positioned at a check-out location, to detect static electricity discharged from foot traffic, shopping cart motions, shopping bag opening and closing, and so on.

The monitoring server 14 processes signals generated by the static electricity sensors 12 and determines from the processed signals a store or shopping-related metric, such as a number of shoppers, shopping carts, shopping bags, and/or a placement of a box on a pallet In some embodiments, the monitoring server 14 includes or other communicates with a conversion device that converts the sensor signals into a data field, for example, a value corresponding to a detected element of static electricity produced from an action of interest, for example, the sensors 12 may detect voltages produced by the static electricity of a person or object of interest. In other examples, the sensors 12 may detect humidity or other conditions. The detected amount of voltage will be determined by the distance away from the item being measured, for example, shopper, shopping bag, currency being exchanged, item on pallet, and so on. For example, a sensor 12 may be configured to detect a 1 volt difference, allowing the system to detect voltage changes at up to 15 feet away. The sensors 12 may have thresholds with respect to received and processed static electricity, and/or other analog data. For example, a sensor 12 may output a result indicating an amount of static electricity detected at a particular location. When a threshold is exceeded or not met, an event signal may be output as digital data electronically to the server 14, which can compare the received data to an associated sensor 12, time, threshold exceeded, and/or other metric data. For example, the monitoring server 14 may process a result by establishing an arrival time of the static electricity. A timestamp or other data element may be formed in response to the sensor 12 detecting a change in voltage, and outputs an event to the server 14. In embodiments where multiple sensors collect such data, the collected data from the different sensors 12 can be used to triangulate where a sensor 12 is collecting the data, and a timestamp can be generated accordingly. The sensors 12 may communicate with a computer or embedded computing device to read the time/threshold data, and subsequently output a generated result to the server 14. This data, for example, amount, location, and time of detected static electricity, may be provided as part of an electronic record that is stored at the static electricity measurement database 18. This data may be general data that is generated by a static sensor 12 to an electronic form, for example, digital output to the server 14. Data from multiple sensors 12 can be correlated by the monitoring server 14. The electronic record may be retrieved by a store computer or the like to process the electronic record as part of a store operation, for example, to determine a number of customers who passed a particular location of the store over a predetermined amount of time, or for monitoring boxes that are loaded and unloaded at a warehouse. In some embodiments, the monitoring server 14 communicates with a store computer or the like that stores data that may be added to an electronic record that includes other contextual information, for example, to establish a location, time, quantity, and so on, regarding a repeatable action, for example, multiple footsteps, counting of money, movement of boxes onto and from pallets, and so on.

In some embodiments, the electronic record is generated for each repeated action. For example, each person walking by a region within a proximity of detection by a sensor 12 may produce a voltage. The sensor signals include data that distinguishes one person's human foot traffic from a shopping cart wheel motion, another person's creation of electricity, and so on by the amount of the generated electrostatic field and/or other factors such as the time that the field as generated. Contextual data regarding the action, i.e., the particular person's movement, may be determined such as a time, location, and amount and so on of the generated electrostatic field. The electronic record can include the contextual data, which can be used to generate metrics. Contextual data may be determined from signals a static electricity sensor 12 and/or other sensors or other devices that collect data to complement the sensor signals, such as cameras which in some examples may provide video surveillance of a person, while the sensor 12 establishes the presence, time, and location of the person. Such data related to a particular repeatable action can be collected and analyzed, for example, applying analytics or statistical analysis tools.

In some examples, the product movement work order database 20 may be used to determine what boxes are needed for the sales floor. The product movement work order database 20 houses data records indicating item status or other data used for generating a metric, for example, what items are low stock or out of stock on the sales floor. In order to determine which items are being received, for example, delivered by a delivery truck, a determination is made at what is expected to be delivered and a load list from the vendor or other entity ordering the products that are in the truck. The sensors 12 may be used to determine according to a triangulation technique or other location determination technique the location that the items were placed on the pallet. This data is then correlated to the pallet. In this example, when the pallet is on the sales floor, a determination is made which items are removed from the pallet. This data is compared to a perceived need on the sales floor. Finally, the location is validated, and matched to the item should be put.

The foregoing produces validation results requires communication between the product movement work order database 20, monitoring server 14, metric processor 16, and static measurement database 18 to ensure that all the correct products are in the right location and that the all the products requested and/or required are indeed taken out. The metric processing device 16 may generate a store metric regarding the repeatable action from the electronic records. For example, a metric may include a number of shoppers, shopping carts, shopping bags, or a placement of a box on a pallet, and so on. This data can be analyzed by a specific data analyzer, analytic apparatus, and/or other computer-based processor.

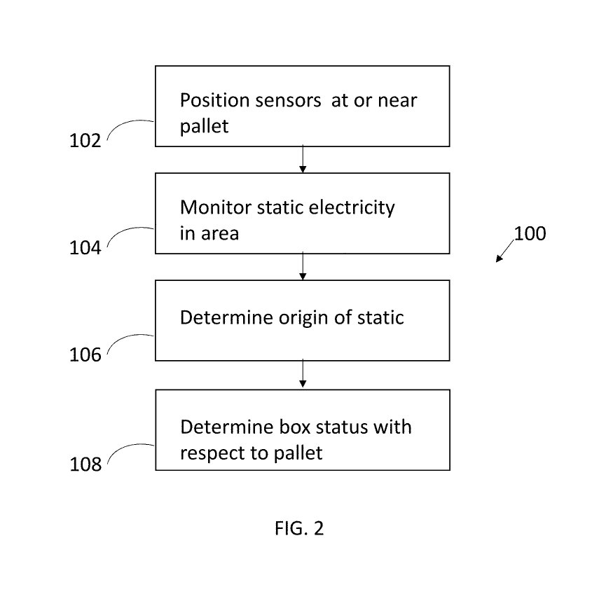

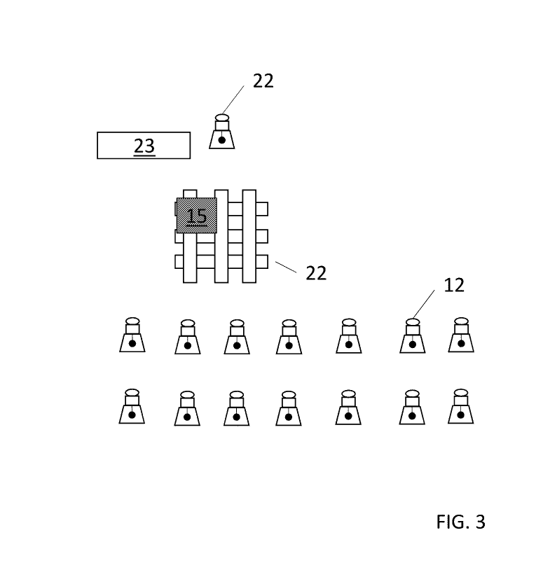

FIG. 2 is a flow diagram of a method 100 for determining a status of boxes loaded on a pallet and removed from the pallet, in accordance with some embodiments. FIG. 3 is a plan view of a store at which the method of FIG. 2 may be implemented, in accordance with some embodiments.

An application of the static electricity sensing system 10 illustrated in FIG. 1 is to determine where a box 15 is placed on a pallet 22 or other storage-related location, for example, at a loading dock 23. In a related application, the static electricity sensing system 10 can determine where a box is taken from on the pallet 22 when the pallet 22 is unloaded, and where the box 15 is placed for unloading.

The electricity sensing system 10 may include one or more static electricity sensors 12 positioned (block 102) on or near the pallet 22, for example, located at a warehouse or other geographic area of the store where the counting of boxes or the like loaded and unloaded from pallets are of interest. For example, the sensors 12 may be positioned at a store shelf where items are stocked and/removed. In another example, sensors 12 at neighboring locations, such as adjacent shelves, may detect when a person is in proximity by static electricity generated by the person. The sensors 12 may determine that a steady rate of static electricity is detected, and detect if increases or decreases in received static electricity. This data can be output to the server 14 and/or database 18, 20. A determination may be made from this data, for example, that the person is tearing cardboard boxes which increases the amount of static electricity produced.

At block 104, static electricity can be monitored by the sensors 12 at the pallet 22. A sensor 12 may determine if there are static electrical charges on the surface of the pallet 22. A sensor 12 may detect other sources of static electricity, for example, generated by a person 11 or shopping cart 13. The sensors 12 may output signals generated in response to detected static electricity to the monitoring server 14, which processes the signals, for example, to establish where static is originating from based upon intensity and arrival times from various sensors 12.

At block 106, the origin of monitored static is determined. For example, the system can determine where static is originating from based on intensity and arrival times of detected static electricity by the various sensors 12.

For example, as shown in FIG. 3, there are two rows of sensors 12. The pallet 22 is near at least one of the sensors. The origin of the static may be determined from a triangulation technique performed using multiple sensors 12, for example, detect static to determine motion through triangulation. With looking at the short history of the sensors 12 and how much they detect, the system can determine direction from and to a location. The server 14 may include analytics technology that can process this data. In some embodiments, for determining time values, a static sensor 12 may include an embedded special-purpose computer to generate the time values.

At block 108, a status of a box or other item on the pallets is determined. For example, a determination can be made if a box 15 has been loaded onto the pallet 22 or unloaded from the pallet 22. Thus, the system can determined where a box is placed on the pallet 22. Similarly, the system can detect where the boxes are taken from and where they are placed for unloading relative to the pallet 22. For example, the presence of a box 15 on a pallet 22 may be sensed by its influence on a static field which changes if the box 15 is moved. The nature of the static field distortion produced by the presence of the box 15 in front of the sensor 12 may be used to identify the box 15 as a box of interest. The effect of moving the box through the field can be to vary the field which can be sensed electrically by the sensor 12. Other information such as time or occurrence of the movement, the amount or intensity of the static electricity, and so on may also be measured. In some embodiments, the system can compel force sensing and non-sensing by placing a box 15 on the ground, whereby any electrical chart may be removed so the sensor 12 cannot sense the presence of the box while it is at rest.

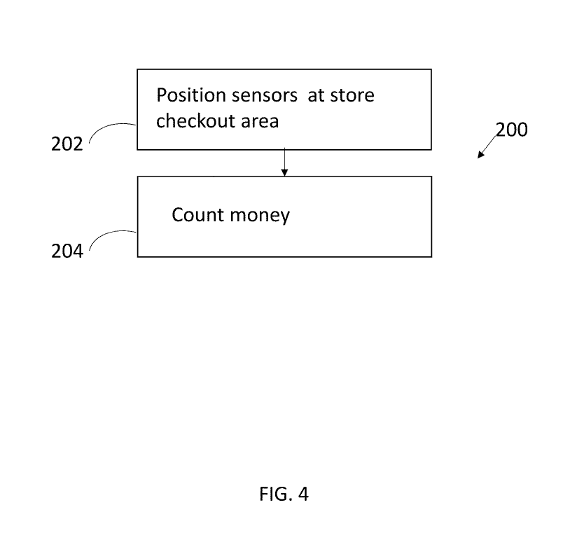

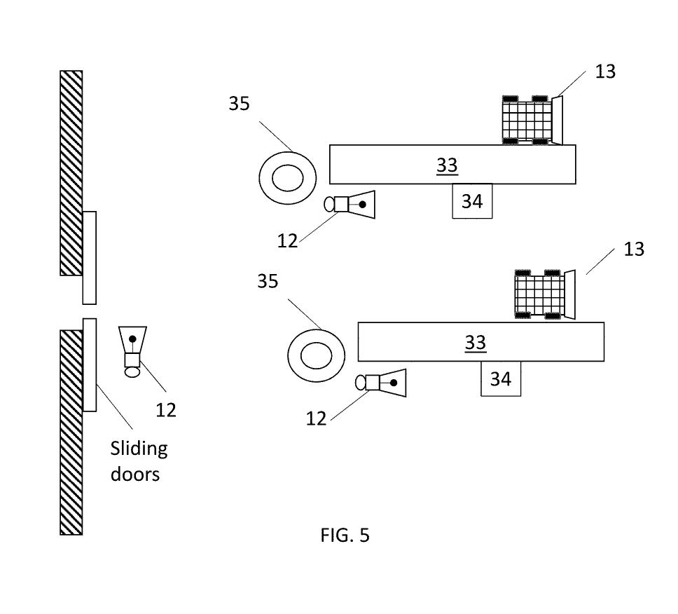

FIG. 4 is a flow diagram of a method 200 for counting money at a point of sale location, in accordance with some embodiments. FIG. 5 is a plan view of a store at which the method 200 of FIG. 4 may be implemented, in accordance with some embodiments. It is well-known that a greater static electricity charge may be present is more currency, in particular, legal tender notes such as dollar bills is present. The method 200 addresses an environment where several notes are stacked together, and where static electricity is produced when adjacent notes are rubbed together during a counting procedure. In describing the method 200, reference may be made to some or all of the elements of FIG. 1, which may be used to execute the method 200.

In general, retail stores rely on currency processing machines and/or store associates to process money received at a point of sale counter, for example, at a checkout area 33 shown in FIG. 5. A cash register 24 or the like at the checkout area 33 may include plurality of currency bills and/or coins. A store customer 11, for example, pushing a shopping cart 13, may also possess currency bills and/or coins used for purchasing store items. A plurality of static electricity sensors 12 are positioned (block 202) at the checkout area 33, for example, near a baggage carousel 35. The sensors 12 can detect a spike in the static electricity produced during counting, i.e., when a force is applied by the dollar bills or the like creating a charge. The detected charge level can be stored and analyzed.

The sensors 12 can be arranged to detect and identify the currency denomination of a currency bill for example produced by a shopper 11 to a store associate at the checkout area 32. For example, a requirement may be that stacked notes are the same, for example, dollar bills in one slot, five dollar bills in another slot, and so on. Each sensor 12 may be allocated to a particular slot. Each sensor 12 can output results which are processed by the monitoring server 14.

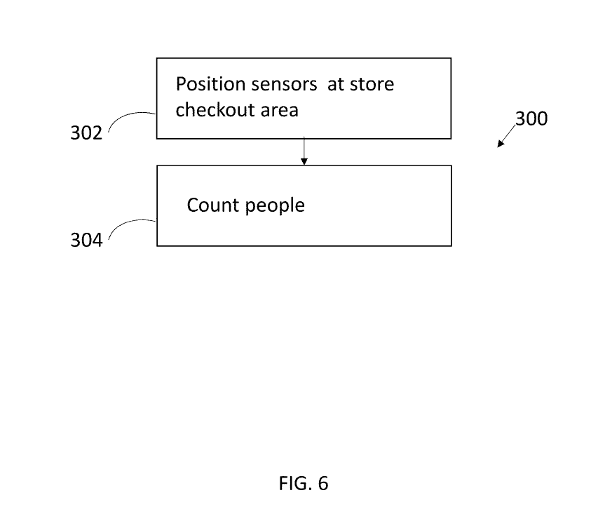

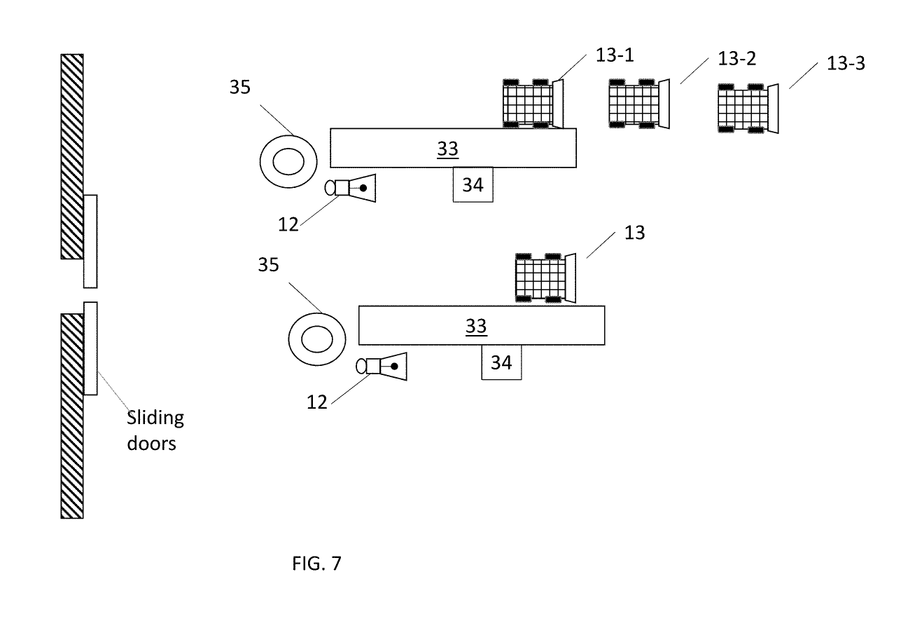

FIG. 6 is a flow diagram of a method 300 for counting people at a store location, in accordance with some embodiments. FIG. 7 is a plan view of a store at which the method 300 of FIG. 6 may be implemented, in accordance with some embodiments. In describing the method 200, reference may be made to some or all of the elements of FIG. 1, which may be used to execute the method 200

Another application of the static electricity sensing system 10 illustrated in FIG. 1 is to count a number of shoppers at a checkout area, such as a checkout lane 33. To achieve this, a plurality of static electricity sensors 12 are positioned (block 302) at the checkout area 33.

One or more sensors 12 located at a particular checkout lane 33 face a direction of the checkout line to detect amount of static electricity at predetermined location of the checkout lane 33. Each time a shopping cart 13 or shopper 11 approaches the predetermined location, the sensor(s) 12 may detect static electricity discharged from foot traffic and shopping cart motions. The sensor(s) 12 may output a detected result to the monitoring server 14 which processes the result by establishing an arrival time of the static electricity. This data, for example, amount, location, and time of detected static electricity, may be provided as part of an electronic record that is stored at the static electricity measurement database 18. The monitoring server 14 may calculate (block 304) a number of people (and/or shopping carts) at the checkout area 33 during a predetermined amount of time. In some embodiments, the sensors 12 may distinguish a person 11 (foot traffic) from a shopping cart 13 (wheel motion) by the intensity or amount of generated static electricity. Accordingly, the system 10 may determine either a number of shopping carts 13 or a number of people 11 passing through the checkout area 33 during a predetermined amount of time. The shopping cart 13 may provide have better detection with the sensors 12 being closer to the floor vs higher up for a person 11. This is due to the wheels of the cart creating the charge and detection being more noticeable near the wheels.

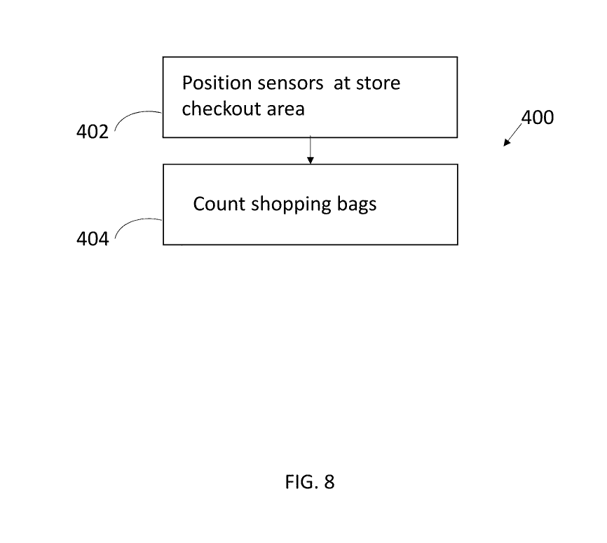

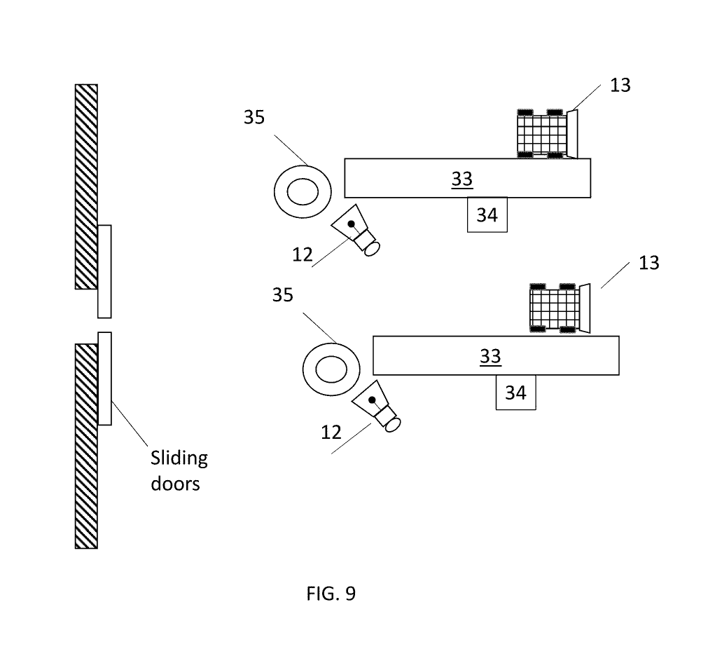

FIG. 8 is a flow diagram of a method 400 for counting shopping bags at a point of sale location, in accordance with some embodiments. FIG. 9 is a plan view of a store at which the method 400 of FIG. 8 may be implemented, in accordance with some embodiments. FIG. 9 is similar to FIGS. 5 and 7 except for the orientation of the sensors 12 toward the bagging carousels 35.

The sensor(s) 12 may output a detected result to the monitoring server 14 which processes the result by establishing an arrival time of the static electricity. This data, for example, amount, location, and time of detected static electricity, may be provided as part of an electronic record that is stored at the static electricity measurement database 18. The monitoring server 14 may calculate (block 404) a number of bags people at the checkout area 33. In some embodiments, the sensors 12 may distinguish the bags from other objects by the intensity or amount of generated static electricity.

As described herein, some or all of the system and method in accordance with some embodiments implemented in a computer system. The computer system may generally comprise a processor, an input device coupled to the processor, an output device coupled to the processor, and memory devices coupled to the processor via a bus or other signal-carrying connector. The processor may perform computations and control the functions of a computer, including executing instructions included in computer code for the tools and programs capable of implementing a method in the manner prescribed by the embodiments of the figures using the system of the figures, wherein the instructions of the computer code may be executed by processor via memory device. The computer code may include software or program instructions that may implement one or more algorithms for implementing the systems and methods, as described in detail above. The processor may execute the computer code.

A memory device may include input data. The input data includes any inputs required by the computer code. The output device may display output from the computer code. The memory device may be used as a computer usable storage medium (or program storage device) having a computer readable program embodied therein and/or having other data stored therein, wherein the computer readable program comprises the computer code. Generally, a computer program product (or, alternatively, an article of manufacture) of the computer system may comprise said computer usable storage medium (or said program storage device).

Memory devices include any known computer readable storage medium, including those described in detail below. In one embodiment, cache memory elements of memory devices may provide temporary storage of at least some program code in order to reduce the number of times code must be retrieved from bulk storage while instructions of the computer code are executed. Moreover, similar to processor, memory device may reside at a single physical location, including one or more types of data storage, or be distributed across a plurality of physical systems in various forms. Further, memory device can include data distributed across, for example, a local area network (LAN) or a wide area network (WAN). Further, memory device may include an operating system (not shown) and may include other systems not shown.

As will be appreciated by one skilled in the art, in a first embodiment, the present inventive concepts may be a method; in a second embodiment, the present inventive concepts may be a system; and in a third embodiment, the present inventive concepts may be a computer program product. Any of the components of the embodiments of the present inventive concepts can be deployed, managed, serviced, etc. by a service provider that offers to deploy or integrate computing infrastructure with respect to systems and methods. Thus, an embodiment of the present inventive concepts discloses a process for supporting computer infrastructure, where the process includes providing at least one support service for at least one of integrating, hosting, maintaining and deploying computer-readable code in a computer system including one or more processor(s), wherein the processor(s) carry out instructions contained in the computer code causing the computer system in accordance with embodiments of the present inventive concepts. Another embodiment discloses a process for supporting computer infrastructure, where the process includes integrating computer-readable program code into a computer system including a processor.

The step of integrating includes storing the program code in a computer-readable storage device of the computer system through use of the processor. The program code, upon being executed by the processor, implements a method of the present inventive concepts. Thus, the present inventive concepts discloses a process for supporting, deploying and/or integrating computer infrastructure, integrating, hosting, maintaining, and deploying computer-readable code into the computer system, wherein the code in combination with the computer system is capable of performing a method of the present inventive concepts.

A computer program product of the present inventive concepts comprises one or more computer readable hardware storage devices having computer readable program code stored therein, said program code containing instructions executable by one or more processors of a computer system to implement the methods of the present inventive concepts.

A computer system of the present inventive concepts comprises one or more processors, one or more memories, and one or more computer readable hardware storage devices, said one or more hardware storage devices containing program code executable by the one or more processors via the one or more memories to implement the methods of the present inventive concepts.

The present inventive concepts may be a system, a method, and/or a computer program product at any possible technical detail level of integration. The computer program product may include a computer readable storage medium (or media) having computer readable program instructions thereon for causing a processor to carry out aspects of the present inventive concepts.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present inventive concepts may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present inventive concepts.

Aspects of the present inventive concepts are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present inventive concepts. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present inventive concepts have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system for determining a store metric from static electricity, comprising:
a plurality of static electricity sensors arranged in a retail environment that detect an electrostatic field produced by a static electric charge, the electrostatic field generated by a repeatable action;
a monitoring server that receives and processes signals generated by the static electricity sensors in response to the detected electrostatic field and generates an electronic record for each action of the repeatable action, the electronic record including contextual data regarding the action, the contextual data in the electronic record including at least one of a time, a location, and an amount of the generated electrostatic field;
a metric processing device that generates a store metric regarding the repeatable action from the electronic records; and
a static electricity measurement database that electronically stores the store metric for subsequent retrieval for analysis.

2. The system of claim 1, wherein the metric includes at least one of number of shoppers, shopping carts, shopping bags, or a placement of a box on a pallet.

3. The system of claim 1, wherein the static electricity sensors are positioned at a store checkout area or a warehouse having pallets.

4. The system of claim 1, wherein the static electricity sensors detect static electricity at wheels of the shopping carts.

5. The system of claim 1, wherein the static electricity sensors detect static electricity from the opening and closing of the shopping bags.

6. The system of claim 5, wherein each time a shopping bag is opened or closed, the system determines where the static is originated according to intensity and arrival times.

7. The system of claim 5, wherein various store metrics are monitored by counting a number of shopping bags opened during a predetermined period of time.

8. The system of claim 1, wherein the system monitors static electricity in an area, and determines where static electricity sources originate from based upon intensity and arrival times from the sensors.

9. The system of claim 1, wherein the static electricity sensors sense other shopping events such as counting money, detecting a location of a shopping cart, detecting acquisition of store items, and detecting shopper actions.

10. The system of claim 1, wherein the sensor includes an electroscope performing coulomb electronic force detection.

11. The system of claim 1, wherein the sensors are positioned on the pallets.

12. The system of claim 1, further comprising a product movement work order database.

13. The system of claim 1, wherein the action includes at least one of human foot traffic and a shopping cart wheel motion and the sensor signals include data that distinguishes the human foot traffic from the shopping cart wheel motion by the amount of the generated electrostatic field.

14. A system for determining a shopping metric from static electricity, comprising:
a plurality of static electricity sensors that determine a status of a box on a pallet in response to detected static electricity, and convert the static electricity into output signals; and
a monitoring server that processes the converted output signals to establish an origination source of the static electricity, and determines from the processed signals a store metric.

15. The system of claim 14, further comprising a static electricity measurement database that stores the store metric for subsequent retrieval for analysis.

16. The system of claim 14, wherein the static electricity sensors determine the origination source by performing a triangulation technique.

17. The system of claim 14, wherein the static electricity sensors determine the origination source based upon intensity and arrival times from the sensors.

18. The system of claim 14, wherein the sensors determine if there are static electrical charges on the surface of the pallet.

19. A method of use of static electricity for determining a store metric, comprising:
receiving by a plurality of static electricity sensors a source of static electricity;
converting the source of static electricity into digital data;
storing the digital data for subsequent retrieval for analysis; and
analyzing the digital data to determine the store metric.
